(19) United States
(12) Patent Application Publication
(10) Pub. No.: US 2026/0032922 A1
(43) Pub. Date: Jan. 29, 2026

(54) HYBRID WIRE SIZE DIAMETER UNDER ONE SINGLE DIE

(71) Applicant: Micron Technology, Inc., Boise, ID (US)

(72) Inventors: Deborah Moizin, Singapore (SG); Amirul Hud, Singapore (SG)

(21) Appl. No.: 18/782,923

(22) Filed: Jul. 24, 2024

(51) Int. Cl. H01L 23/00; H01L 25/18; H10B 80/00

(52) U.S. Cl. CPC H01L 24/49; H01L 24/04; H01L 24/05; H01L 24/06; H10B 80/00; H01L 25/18; H01L 2224/04042; H01L 2224/05553; H01L 2224/05554; H01L 2224/06131; H01L 2224/06515; H01L 2224/4903; H01L 2224/49175; H01L 2924/1436; H01L 2924/1437; H01L 2924/1438

(57) ABSTRACT

Systems and apparatus are provided for a hybrid wire size diameter under one single die. For example, an apparatus can include a memory cell die, a plurality of signal pads under the memory cell die and a plurality of power pads under the memory cell die. Each bonding wire coupled to a respective one of the plurality of signal pads has a first wire size diameter and each bonding wire coupled to a respective one of the plurality of power pads has a second wire size diameter larger than the first wire size diameter.

### TECHNICAL FIELD

The present disclosure relates generally to memory devices, and more particularly, to a hybrid wire size diameter under a single die.

### BACKGROUND

Memory devices are typically provided as internal, semiconductor, integrated circuits in computers or other electronic systems. There are many different types of memory including volatile and non-volatile memory. Volatile memory can require power to maintain its data (e.g., host data, error data, etc.) and includes random access memory (RAM), dynamic random access memory (DRAM), static random access memory (SRAM), synchronous dynamic random access memory (SDRAM), and thyristor random access memory (TRAM), among others. Non-volatile memory can provide persistent data by retaining stored data when not powered and can include NAND flash memory, NOR flash memory, ferroelectric random access memory (FeRAM), and resistance variable memory such as phase change random access memory (PCRAM), resistive random access memory (RRAM), and magnetoresistive random access memory (MRAM), such as spin torque transfer random access memory (STT RAM), among others.

Memory devices may be coupled to a host (e.g., a host computing device) to store data, commands, and/or instructions for use by the host while the computer or electronic system is operating. For example, data, commands, and/or instructions can be transferred between the host and the memory device(s) during operation of a computing or other electronic system. A controller may be used to manage the transfer of data, commands, and/or instructions between the host and the memory devices.

### BRIEF DESCRIPTION OF THE DRAWINGS

FIG. 1 is a block diagram of an apparatus in the form of a computing system including a memory device in accordance with a number of embodiments of the present disclosure.

FIG. 2 illustrates a block diagram of an apparatus in the form of a memory die in accordance with a number of embodiments of the present disclosure.

FIG. 3 illustrates a diagram of hybrid wire sizes in accordance with a number of embodiments of the present disclosure.

FIG. 4 illustrates a block diagram of a system including stacked memory dies in accordance with a number of embodiments of the present disclosure.

FIG. 5 illustrates an example machine of a computer system within which a set of instructions, for causing the machine to perform various methodologies discussed herein, can be executed.

### DETAILED DESCRIPTION

Embodiments of the present disclosure describe a hybrid wire size diameter under a single die. Die connections can include the use of power and signal pads, for example. With wire bonding, power pads on a memory die (also referred to herein as a “memory cell die”) can be connected by bonding wires to a power plan. Bonding wires, for example, may be gold (Au), aluminum, copper, or similar conductive metal wire. Signal pads on the die may be linked through bonding wire to a substrate signal pad and from that pad the signal may be traced to upper or lower surface pads through conductive layer features and vias and connected to solder balls.

As design rules shrink, less semiconductor space is available to fabricate memory, including volatile (e.g., DRAM) and non-volatile (e.g., NAND) arrays, among others. Smaller die sizes can result in failing power signal integrity (PSI) due to IR drop. For example, as current flows through a resistor, the voltage drops—this can be referred to as IR drop. Put another way, an IR drop is the potential difference, or voltage drop, between two ends of a conducting wire during current flow. When voltage drops, circuit timing can be affected and/or a functional failure can occur, among other issues. Failing PSI can indicate that a desired voltage and current are not met from a source to a destination (e.g., power integrity), and/or that a desired quality of an electrical signal is not met (e.g., signal integrity).

Examples of the present disclosure can address the issue of PSI failure by utilizing a hybrid wire size diameter under one signal memory die. For instance, integrating a hybrid wire size diameter under the memory die can improve IR drop, while maintaining a desired (e.g., small) memory die size. For instance, a power pad under the memory die can have a bonding wire coupled thereto having a first diameter (e.g., about 1.0 millimeters), while a signal pad under the memory die can have a bonding wire coupled thereto having a second diameter smaller than the first diameter (e.g., about 0.7 millimeters). For instance, because an IR drop may be affected more by the power pads and associated bonding wires as opposed to the signal pads and associated bonding wires, the power pads and associated bonding wires can have a thicker diameter to reduce IR drop, while the signal pads and associated bonding wires can have a thinner diameter as the signal may not require the thicker bonding wire diameter.

Embodiments of the present disclosure are directed to an apparatus that includes a memory cell die, a plurality of signal pads under the memory cell die and a plurality of power pads under the memory cell die. Each bonding wire coupled to a respective one of the plurality of signal pads can have a first wire size diameter, and each bonding wire coupled to a respective one of the plurality of power pads can have a second wire size diameter larger than the first wire size diameter.

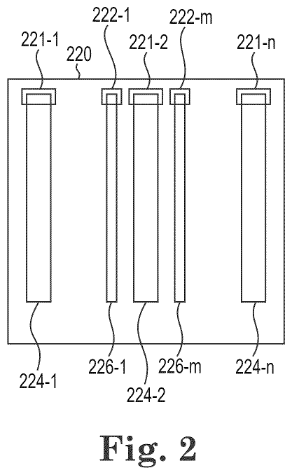

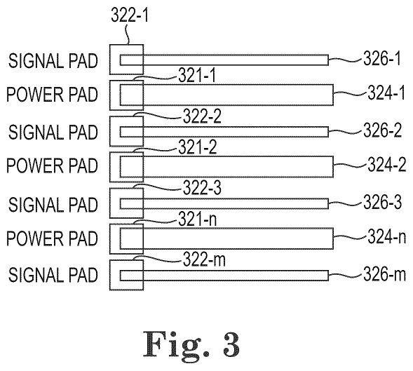

The figures herein follow a numbering convention in which the first digit or digits correspond to the drawing figure number and the remaining digits identify an element or component in the drawing. Similar elements or components between different figures may be identified by the use of similar digits. For example, 221 may reference element “21” in FIG. 2, and a similar element may be referenced as 321 in FIG. 3. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate certain embodiments of the present invention and should not be taken in a limiting sense.

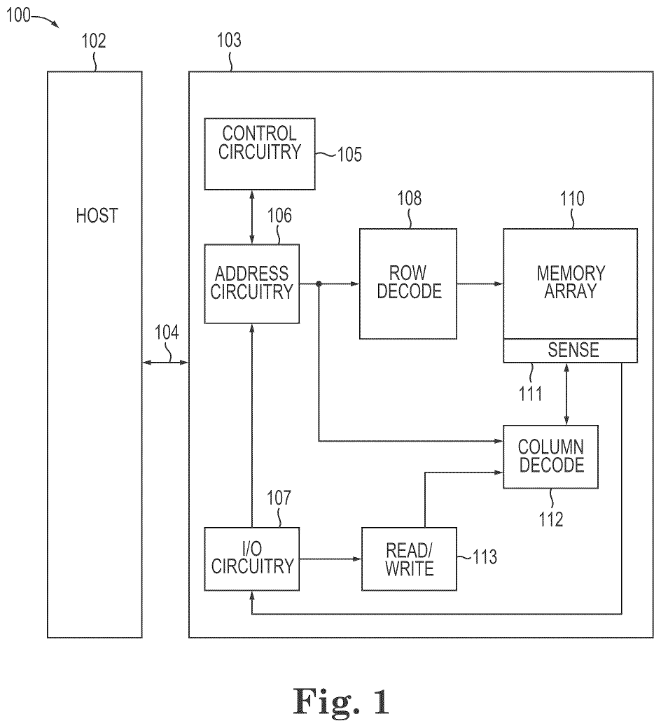

FIG. 1 is a block diagram of an apparatus in the form of a computing system 100 including a memory device 103 in accordance with a number of embodiments of the present disclosure. As used herein, a memory device 103, memory array 110, and/or a host 102, for example, might also be separately considered an “apparatus.”

In various examples, the computing system 100 includes a host 102 coupled to memory device 103 via an interface 104. The memory device 103 can be coupled to a memory module which is coupled to the computing system 100 via the interface 104. The computing system 100 can be a personal laptop computer, a desktop computer, a digital camera, a mobile telephone, a memory card reader, or an Internet-of-Things (IOT) enabled device, among various other types of systems. The host 102 can include a number of processing resources (e.g., one or more processors, microprocessors, or some other type of controlling circuitry) capable of accessing the memory device 103. The computing system 100 can include separate integrated circuits, or both the host 102 and the memory device 103 can be on the same integrated circuit. For example, the host 102 may be a system controller of a memory system comprising multiple memory devices 103, with the system controller providing access to the respective memory devices 103 by another processing resource such as a central processing unit (CPU).

In the example shown in FIG. 1, the host 102 is responsible for executing an operating system (OS) and/or various applications that can be loaded thereto (e.g., from memory device 103 via control circuitry 105). The OS and/or various applications can be loaded from the memory device 103 by providing access commands from the host 102 to the memory device 103 to access the data comprising the OS and/or the various applications. The host 102 can also access data utilized by the OS and/or various applications by providing access commands to the memory device 103 to retrieve said data utilized in the execution of the OS and/or the various applications.

For clarity, the computing system 100 has been simplified to focus on features with particular relevance to the present disclosure. The memory array 110 can be a DRAM array, SRAM array, STT RAM array, PCRAM array, TRAM array, RRAM array, NAND flash array, NOR flash array, and/or 3D Cross-point array for instance. The memory array 110 can comprise memory cells arranged in rows coupled by access lines (which may be referred to herein as word lines or select lines) and columns coupled by sense lines (which may be referred to herein as digit lines or data lines). Although the memory array 110 is shown as a single memory array, the memory array 110 can represent a plurality of memory arrays arraigned in banks of the memory device 103.

The memory device 103 includes address circuitry 106 to latch address signals provided over an interface 104. The interface can include, for example, a physical interface (e.g., a data bus, an address bus, and a command bus, or a combined data/address/command bus) employing a suitable protocol. The physical interface can also include a memory slot to which a memory module comprising the memory device 103 is coupled. The physical interface can also include an array area to which the memory device 103 is directly coupled. Such protocol may be custom or proprietary, or the interface 104 may employ a standardized protocol, such as Peripheral Component Interconnect Express (PCIe), Gen-Z interconnect, cache coherent interconnect for accelerators (CCIX), or the like. Address signals are received and decoded by a row decoder 108 and a column decoder 112 to access the memory arrays 110. Data can be read from memory arrays 110 by sensing voltage and/or current changes on the sense lines using sensing circuitry 111. The sensing circuitry 111 can be coupled to the memory arrays 110. Each memory array and corresponding sensing circuitry can constitute a bank of the memory device 103. The sensing circuitry 111 can comprise, for example, sense amplifiers that can read and latch a page (e.g., row) of data from the memory array 110. The I/O circuitry 107 can be used for bi-directional data communication with the host 102 over the interface 104. The read/write circuitry 113 is used to write data to the memory arrays 110 or read data from the memory arrays 110. As an example, the read/write circuitry 113 can comprise various drivers, latch circuitry, etc.

Control circuitry 105 decodes signals provided by the host 102. The signals can be commands provided by the host 102. These signals can include chip enable signals, write enable signals, and address latch signals that are used to control operations performed on the memory array 110, including data read operations, data write operations, and data erase operations. In various embodiments, the control circuitry 105 is responsible for executing instructions from the host 102. The control circuitry 105 can comprise a state machine, a sequencer, and/or some other type of control circuitry, which may be implemented in the form of hardware, firmware, or software, or any combination of the three. In some examples, the host 102 can be a controller external to the memory device 103. For example, the host 102 can be a memory controller which is coupled to a processing resource of a computing device. Data can be provided to the memory array 110 and/or from the memory array via the data lines coupling the memory array 110 to the I/O circuitry 107.

In various instances, a memory die of the memory device 103 can utilize hybrid wire size diameters with respect to power pads and signal pads beneath the memory die allowing for desired performance with a smaller die size.

FIG. 2 illustrates a block diagram of an apparatus in the form of a memory die 220 (e.g., non-volatile memory cell die, volatile memory cell die, etc.) in accordance with a number of embodiments of the present disclosure. The memory cell die 220 can include beneath it power pads 221-1, . . . 221-n and signal pads 222-1, 222-m. In some examples, power pads 221 may be located closer to an exterior of the memory cell die as compared to signal pads 222.

The power pads 221 can be the pads that are generally responsible for the electric connection between components of a power circuit; since the current level passing through the power pads 221 is higher as compared to the signal pads 222, the power pads 221 may be thicker and/or the cross-sectional area of the power pads 221 is bigger, although examples are not so limited. The signal pads 222 can be responsible for transmitting the signal in a converter; for example, a control circuit in a control unit may transmit a control signal to a circuit through the signal pads 222 to control the conduction and turning-off of power components. In some examples, a current level passing through signal pads 222 is lower, and the pads may be thinner and/or the cross-sectional area thereof may be smaller, although examples are not so limited.

The memory cell die 220 can include a first section comprising a first plurality of power pads 222-1 under a first section of the memory cell die 220 and a second section comprising a second plurality of power pads 221-n under a second section of the memory cell die 220. Each bonding wire 224-1 coupled to a respective one of the first plurality of power pads 221-1 and each bonding wire 224-n coupled to a respective one of the second plurality of power pads 221-n can have a first wire size diameter, for example 1.0 millimeters.

The memory cell die 220 can include a third section comprising a plurality of signal pads 222-1, . . . , 222-m under a third section of the memory cell die 220 and between the first plurality of power pads 221-1 and the second plurality of power pads 221-n. Each bonding wire 226 coupled to a respective one of the plurality of signal pads can have a second wire size diameter smaller than the first wire size diameter (e.g., 0.7 millimeters). In some examples, an individual power pad 221-2 can be located within the third section and between two signal pads 222-1 and 222-m. The bonding wire 224-2 coupled to the individual power pad 221-2 can have the first, larger wire size diameter.

As noted, power pads 221 may be located closer to an exterior of the memory cell die as compared to signal pads 222 For example, the first section of the memory cell die 220 (e.g., including power pad 221-2) can be located below a first outer edge of the memory cell die 220, and the second section of the memory cell die 220 (e.g., including signal pad 221-n) can be located below a second outer edge of the memory cell die opposite the first outer edge of the memory cell die. The third section (e.g., including power pad 221-2 and/or signal pads 222-1, . . . , 222-m) can be located below an approximate center of the memory cell die, in some examples.

A different memory cell die can be stacked on the memory cell die 220, in some examples. For instance, the different memory cell die can include a different plurality of signal pads under the different memory cell die and a different plurality of power pads under the different memory cell die. Each bonding wire coupled to a respective one of the different plurality of signal pads can have the first wire size diameter (e.g., 0.7 millimeters), and each bonding wire coupled to a respective one of the different plurality of power pads can have the second wire size diameter (e.g., 1.0 millimeters). While 0.7 millimeters and 1.0 millimeters are used as examples, herein, the first and the second wire size diameters may vary, as long as the second wire size diameter (e.g., associated with the power pads 221) is larger than the first wire size diameter (e.g., associated with the signal pads 222).

FIG. 3 illustrates a diagram of hybrid wire sizes in accordance with a number of embodiments of the present disclosure. A memory die can include alternating signal pads 322-1, 322-2, . . . , 322-m and power pads 321-1, 321-2, . . . , 321-n having different wire sizes associated therewith. The plurality of signal pads 322 coupled under the memory cell die can include bonding wires 326, and the bonding wires 326 can have a first wire size diameter. The plurality of power pads 321 coupled under the memory cell die can include bonding wires 324, and the bonding wires 324 can have a second wire size diameter larger than the first wire size diameter. For instance, the bonding wires 326 can have a diameter of approximately 0.7 millimeters, and the bonding wires 324 can have a diameter of approximately 1.0 millimeters. An “approximate” diameter can include a diameter larger or smaller than the stated 0.7 millimeters and 1.0 millimeters diameters. For instance, the bonding wires 326 may have a diameter of 0.6 millimeters, and the bonding wires 324 may have a diameter of 0.9 millimeters.

The bonding wires 324 having a larger diameter as compared to the bonding wires 326 can allow for a smaller size of memory cell die and/or a tighter bond pitch size (e.g., signal pads 322 and power pads 321 can be closer together). The distance between a power pad such as power pad 321-2 and an adjacent signal pad, such as signal pad 322-1 can be below a distance threshold allowing for the smaller die size. For instance, the distance threshold can be the size of the smaller of the power pad 321-2 and the signal pad 322-1. As will be discussed further herein, a distance between the power pads 321, bonding wires 324 and the power pads 322 and bonding wires 326 can reduce a wire bond shorting risk.

By maintaining a larger diameter for the bonding wires 324, while reducing a diameter (e.g., from a typical 1.0 millimeters to 0.7 millimeters) of the bonding wires 326, an IR drop can be reduced, as IR drop is associated with power pads 321 more so than signal pads 322. Additionally, hybrid bonding wire sizes keep the bonding wires 324 and 326 at a threshold distance from one another, allowing for a reduction of wire bond shorting risk, as the bonding wires 324 and 326 are less likely to come into contact with one another. Additionally, wire bonding fanout can be reduced as compared to having a larger wire diameter for the signal bonding wires 326 and the power bonding wires 324.

In some examples, at least a portion of the plurality of signal pads 322 and power pads 321 are arranged in an alternating pattern. For example, as illustrated in FIG. 3, signal pads 322-1 and 322-2 are in an alternating pattern with power pad 321-1 and 321-2.

The signal bonding wires 326 and the power bonding wires 324 can be assembled, for instance, by utilizing first a smaller diameter bonding machine (e.g., a 0.7 millimeter bonding machine), followed by a larger diameter bonding machine (e.g., a 1.0 millimeter bonding machine). A wire bond pull and shear process, for instance, can include separating the pull and shear into two data sets (e.g., signal bonding wire size and power bonding wire size). The pull and shear can be performed on the smaller diameter wire and then the larger diameter wire. Force data may be different on the smaller wire as compared to the larger wire, and this can be used to set appropriate parameters. In some examples, a same hook and shear tool can be used for the larger and the smaller wires.

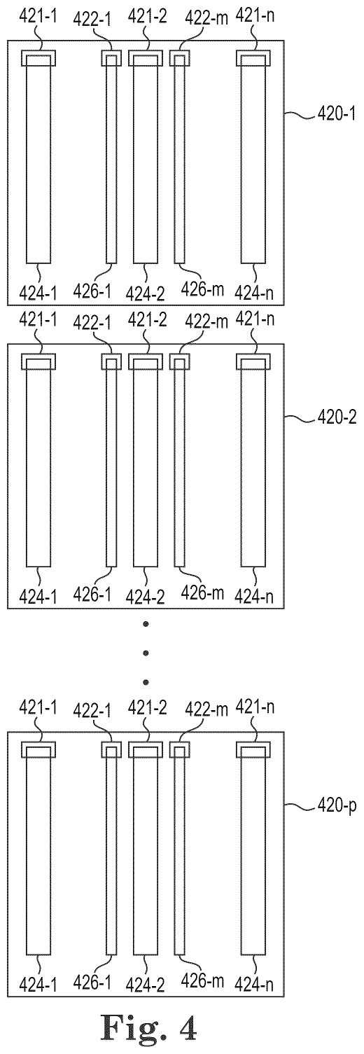

FIG. 4 illustrates a block diagram of a system including stacked memory dies 420-1, 420-2, . . . , 420-p in accordance with a number of embodiments of the present disclosure. The stack, for instance, can include a stack of non-volatile memory cell dies or a stack of volatile memory cell dies. The stack, for instance, may include a stack of sixteen memory cell dies, although other size memory cell die stacks may be utilized.

Each memory cell die of the stack of memory cell dies 420-1, 420-2, . . . , 420-p can include a plurality of alternating signal pads 421 and power pads 422 under the memory cell die 420 Each bonding wire 426 coupled to a respective one of the plurality of signal pads 422 can have a first wire size diameter (e.g., 0.7 millimeters), and each bonding wire 424 coupled to a respective one of the plurality of power pads 421 can have a second wire size diameter (e.g., 1.0 millimeters) larger than the first wire size diameter.

In some examples, each bonding wire 426 coupled to a respective one of the plurality of signal pads 422 is separated from an adjacent bonding wire 424 coupled to a respective one of the plurality of signal pads 421 by a distance that reduces a wire bond shorting risk below a particular threshold risk. The threshold risk, for instance, may be set by a manufacturer such that some risk is acceptable. By alternating bonding wire sizes, the risk of the bonding wires contacting one another and shorting is reduced, particularly as compared to bonding wire sizes that are constant (e.g., all 1.0 millimeter bonding wire diameters on a reduced-size die).

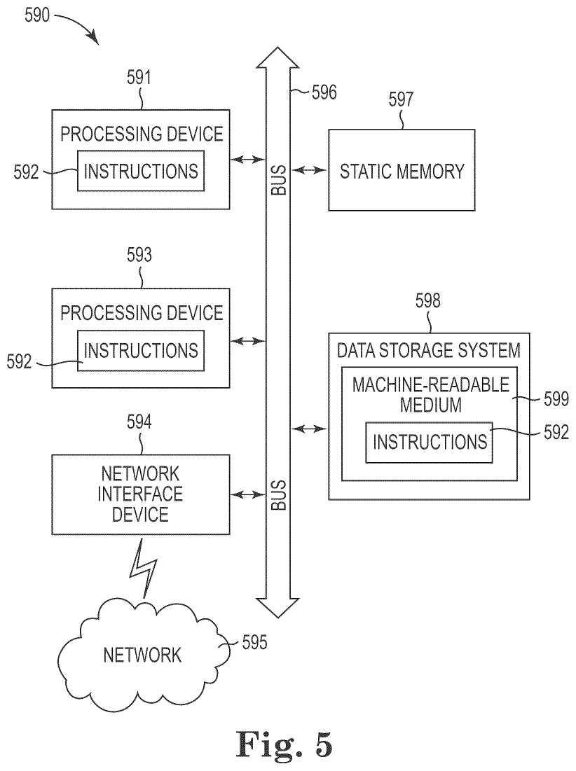

FIG. 5 illustrates an example machine of a computer system 590 within which a set of instructions, for causing the machine to perform various methodologies discussed herein, can be executed. In various embodiments, the computer system 590 can correspond to a system (e.g., the computing system 100 of FIG. 1) that includes, is coupled to, or utilizes a memory sub-system (e.g., the memory device 103 of FIG. 1) or can be used to perform the operations of a controller (e.g., the controller circuitry 105 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 590 includes a processing device 591, a main memory 593 (e.g., read-only memory (ROM), flash memory, dynamic random access memory (DRAM) such as synchronous DRAM (SDRAM) or Rambus DRAM (RDRAM), etc.), a static memory 597 (e.g., flash memory, static random access memory (SRAM), etc.), and a data storage system 598, which communicate with each other via a bus 596.

Processing device 591 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 591 can also be one or more special-purpose processing devices such as an application specific integrated circuit (ASIC), a field programmable gate array (FPGA), a digital signal processor (DSP), network processor, or the like. The processing device 591 is configured to execute instructions 592 for performing the operations and steps discussed herein. The computer system 590 can further include a network interface device 594 to communicate over the network 595.

The data storage system 598 can include a machine-readable storage medium 599 (also known as a computer-readable medium) on which is stored one or more sets of instructions 592 or software embodying any one or more of the methodologies or functions described herein. The instructions 592 can also reside, completely or at least partially, within the main memory 593 and/or within the processing device 591 during execution thereof by the computer system 590, the main memory 593 and the processing device 591 also constituting machine-readable storage media.

In one embodiment, the instructions 592 include instructions to implement functionality corresponding to the host 102 and/or the memory device 103 of FIG. 1. While the machine-readable storage medium 599 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

As used herein, “a number of” something can refer to one or more of such things. For example, a number of memory devices can refer to one or more memory devices. A “plurality” of something intends two or more. Additionally, designators such as “N,” as used herein, particularly with respect to reference numerals in the drawings, indicates that a number of the particular feature so designated can be included with a number of embodiments of the present disclosure.

As will be appreciated, elements shown in the various embodiments herein can be added, exchanged, and/or eliminated so as to provide a number of additional embodiments of the present disclosure. In addition, the proportion and the relative scale of the elements provided in the figures are intended to illustrate various embodiments of the present disclosure and are not to be used in a limiting sense.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one.

Combinations of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

In the foregoing Detailed Description, various features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. An apparatus, comprising:
a memory cell die;
a plurality of signal pads under the memory cell die, wherein each bonding wire coupled to a respective one of the plurality of signal pads has a first wire size diameter; and
a plurality of power pads under the memory cell die, wherein each bonding wire coupled to a respective one of the plurality of power pads has a second wire size diameter larger than the first wire size diameter.

2. The apparatus of claim 1, wherein at least a portion of the plurality of signal pads and the plurality of power pads are arranged in an alternating pattern.

3. The apparatus of claim 1, wherein the first wire size diameter is approximately 0.7 millimeters.

4. The apparatus of claim 1, wherein the second wire size diameter is approximately 1.0 millimeters.

5. The apparatus of claim 1, wherein the memory cell die is a non-volatile memory cell die.

6. The apparatus of claim 1, wherein the memory cell die is a volatile memory cell die.

7. The apparatus of claim 1, further comprising a different memory cell die stacked on the memory cell die and comprising:
a different plurality of signal pads under the different memory cell die, wherein each bonding wire coupled to a respective one of the different plurality of signal pads has the first wire size diameter; and
a different plurality of power pads under the different memory cell die, wherein each bonding wire coupled to a respective one of the different plurality of power pads has the second wire size diameter.

8. The apparatus of claim 1, wherein a distance between a power pad of the plurality of power pads and an adjacent signal pad of the plurality of signal pads is below a distance threshold.

9. The apparatus of claim 8, wherein the distance threshold comprises a size of the smaller of the power pad or the signal pad.

10. An apparatus, comprising:
a stack of memory cell dies, wherein each memory cell die in the stack comprises:
a plurality of alternating signal pads and power pads under the memory cell die,
wherein each bonding wire coupled to a respective one of the plurality of signal pads has a first wire size diameter; and
wherein each bonding wire coupled to a respective one of the plurality of power pads has a second wire size diameter larger than the first wire size diameter.

11. The apparatus of claim 10, wherein the stack of memory cell dies comprises a stack of non-volatile memory cell dies.

12. The apparatus of claim 10, wherein the stack of memory cell dies comprises a stack of volatile memory cell dies.

13. The apparatus of claim 10, wherein the stack of memory cell dies comprises a stack of sixteen memory cell dies.

14. The apparatus of claim 10, wherein each bonding wire coupled to a respective one of the plurality of signal pads is separated from an adjacent bonding wire coupled to a respective one of the plurality of signal pads by a distance that reduces a wire bond shorting risk below a particular threshold risk.

15. The apparatus of claim 10, wherein the first wire size diameter is approximately 0.7 millimeters, and wherein the second wire size diameter is approximately 1.0 millimeters.

16. A system, comprising:
a memory cell die;
a first section comprising a first plurality of power pads under a first section of the memory cell die;
a second section comprising a second plurality of power pads under a second section of the memory cell die,
wherein each bonding wire coupled to a respective one of the first plurality of power pads and each bonding wire coupled to a respective one of the second plurality of power pads has a first wire size diameter; and
a third section comprising a plurality of signal pads under a third section of the memory cell die and between the first plurality of power pads and the second plurality of power pads,
wherein each bonding wire coupled to a respective one of the plurality of signal pads has a second wire size diameter smaller than the first wire size diameter.

17. The system of claim 16, further comprising an individual power pad located within the third section and between two of the plurality of signal pads.

18. The system of claim 17, wherein a bonding wire coupled to the individual power pad comprises the first wire size diameter.

19. The system of claim 16, wherein the first section of the memory cell die is located below a first outer edge of the memory cell die, and the second section of the memory cell die is located below a second outer edge of the memory cell die opposite the first outer edge of the memory cell die.

20. The system of claim 16, wherein the third section of the memory cell die is located below an approximate center of the memory cell die.
